(19) United States
(12) Patent Application Publication
(10) Pub. No.: US 2006/0108690 A1
(43) Pub. Date: May 25, 2006

(54) Circuit board with reduced simultaneous switching noise

(75) Inventors: Sung-Mao Wu, Kaohsiung County (TW); Chi-Tsung Chiu, Kaohsiung City (TW); Chih-Pin Hung, Kaohsiung City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/183,824

(22) Filed: Jul. 19, 2005

(30) Foreign Application Priority Data
Nov. 19, 2004 (TW) 93135598

(51) Int. Cl. H01L 23/48

(52) U.S. Cl. 257/758; 257/774

(57) ABSTRACT

A circuit board with reduced simultaneous switching noise. The circuit board comprises a first conductor plane with a first fixed potential, a dielectric layer, at least a build-up via and a second conductor plane with a second fixed potential. The dielectric layer is formed on the first conductor plane. The build-up vias are formed in the dielectric layer and filled with a conductive material. The second conductor plane is in contact with the conductive material in the build-up vias. The depth of the build-up vias is less than one fourth of a signal wavelength.

### BACKGROUND

The invention relates to semiconductor packaging and, in particular, to a circuit board with reduced simultaneous switching noise.

Since operating speed of packaged circuits is concerned with evaluation of power planes, voltage stability of power planes is very important during operation of high frequency/high speed circuits. When many output drivers simultaneously switch, large currents are crowded into a ground end or power supply end, thus generating simultaneous voltage change of power distribution of a chip or packaged sample. The simultaneous switch causes a simultaneous voltage difference between ground potentials of a chip internal ground and a system ground. The offset of ground potential is simultaneous switching noise, expressed as V=L(di/dt). The voltage change of a simultaneous switching noise is proportional to inductances coupled to power and a rate of current change. As semiconductor circuits have become more integrated, larger inductances are imposed on longer routings. The simultaneous switching noise also becomes more prominent.

To overcome the simultaneous switching noise issue, decoupling capacitors are traditionally disposed at specific locations on power planes during packaging substrate design. The decoupling capacitors are typically chip-type capacitors such that an impact on power planes can be minimized during operation of high frequency/high speed circuits.

However, additional discrete chip-type capacitors increase packaging cost and failure probability, detrimentally affecting reliability.

### SUMMARY

An embodiment of a circuit board with reduced simultaneous switching noise utilizes an electric field disturbance resulting from generated current when a via is parallel to an electric field. Thus, the simultaneous switching noise can be suppressed.

An embodiment of a circuit board with reduced simultaneous switching noise comprises a first conductor plane with a first fixed potential, a dielectric layer, at least a build-up via and a second conductor plane with a second fixed potential. The dielectric layer is formed on the first conductor plane. The build-up vias are formed in the dielectric layer and filled with a conductive material. The second conductor plane is in contact with the conductive material in the build-up vias. The depth of the build-up vias is less than one fourth of a signal wavelength.

Another embodiment of a circuit board with reduced simultaneous switching noise comprises a first conductor plane with a first fixed potential, a dielectric layer, at least a build-up via and a second conductor plane with a second fixed potential. The dielectric layer is formed on the first conductor plane. The build-up vias are formed in the dielectric layer and filled with a conductive material. The second conductor plane is in contact with the conductive material in the build-up vias. Distances between the build-up vias substantially equal one fourth of a signal wavelength.

Embodiments of a circuit board with reduced simultaneous switching noise are provided with two characteristics. First, use of chip-type capacitors is minimized. Cost is reduced and routing flexibility increased. Second, use of high-K or low-K dielectric materials in a packaging substrate is minimized, thus avoid reliability issues.

### BRIEF DESCRIPTION OF THE DRAWINGS

FIG. 1 shows a circuit board with reduced simultaneous switching noise according to an embodiment of the invention.

FIG. 2 shows a circuit board with reduced simultaneous switching noise according to another embodiment of the invention.

### DETAILED DESCRIPTION

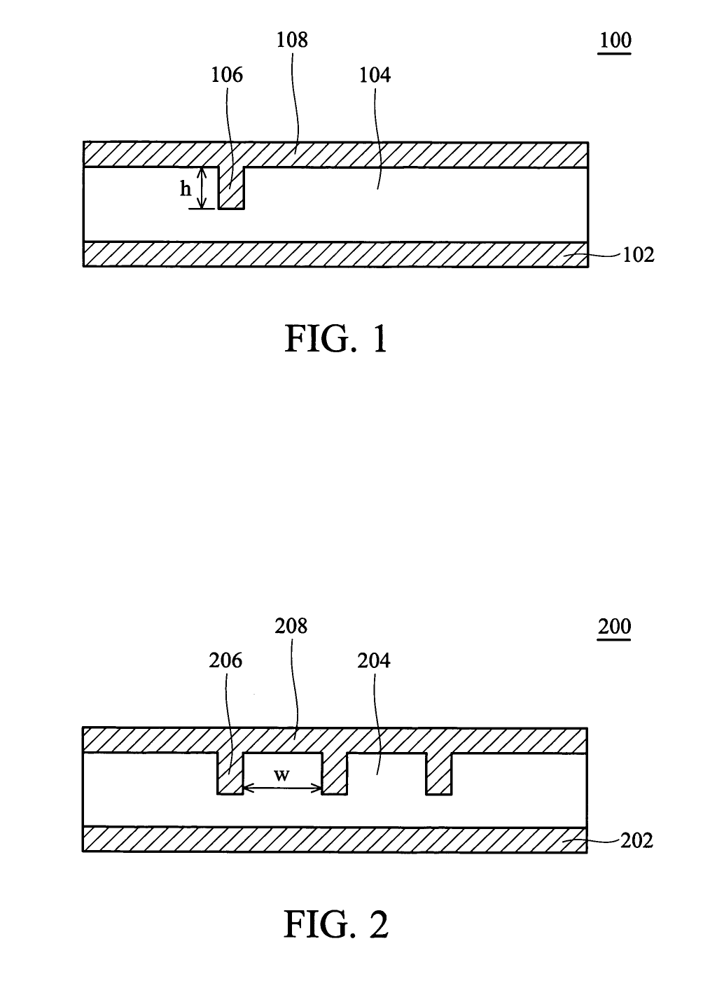

FIG. 1 shows a circuit board 100 with reduced simultaneous switching noise according to an embodiment of the invention. The circuit board 100 comprises a first conductor plane 102 with a first fixed potential, a dielectric layer 104, at least one build-up via 106 and a second conductor plane 108 with a second fixed potential. The dielectric layer 104 is formed on the first conductor plane 102. The build-up vias 106 are formed in the dielectric layer 104 by mechanical or photolithographic methods. In addition, the build-up vias 106 are filled with a conductive material by electroless-plating or electro-plating. The second conductor plane 108 is in contact with the conductive material in the build-up vias 106. The depth h of the build-up vias is less than one fourth of a signal wavelength.

The first conductor plane can be a power plane and the second conductor plane a ground plane. Alternatively, the first conductor plane can be a ground plane and the second conductor plane a power plane. The conductor planes and the conductive material in the inductor inducing build-up via are typically formed of the same metal. Preferably, the metal is copper.

FIG. 2 shows a circuit board 200 with reduced simultaneous switching noise according to another embodiment of the invention. The circuit board 200 comprises a first conductor plane 202 with a first fixed potential, a dielectric layer 204, at least one build-up via 206 and a second conductor plane 208 with a second fixed potential. The dielectric layer 204 is formed on the first conductor plane 202. The build-up vias 206 are formed in the dielectric layer 204 and filled with a conductive material. The second conductor plane 208 is in contact with the conductive material in the build-up vias 206. Distances W between the build-up vias substantially equal one fourth of a signal wavelength.

Furthermore, the first conductor plane can be a power plane and the second conductor plane a ground plane. Alternatively, the first conductor plane can be a ground plane and the second conductor plane a power plane. The conductor planes and the conductive material in the inductor inducing build-up via are typically formed of the same metal. Preferably, the metal is copper.

Embodiments of a circuit board with reduced simultaneous switching noise are provided with two characteristics. Use of chip-type capacitors is minimized. Cost is reduced and routing flexibility increased. Second, use of high-K or low-K dielectric materials in a packaging substrate is minimized.

While the invention has been described by way of example and in terms of preferred embodiment, it is to be understood that the invention is not limited thereto. To the contrary, it is intended to cover various modifications and (as would be apparent to those skilled in the art). Therefore, the scope of the appended claims should be accorded the broadest interpretation so as to encompass all such modifications.

What is claimed is:

1. A circuit board, comprising:
a first conductor plane with a first fixed potential;
a dielectric layer formed on the first conductor plane;
at least a via formed in the dielectric layer and filled with a conductive material; and
a second conductor plane with a second fixed potential, in contact with the conductive material in the via;
wherein a depth of the via is less than one fourth of a signal wavelength.

2. The circuit board as claimed in claim 1, wherein the first conductor plane is a power plane and a second conductor plane is a ground plane.

3. The circuit board as claimed in claim 1, wherein the first conductor plane is a ground plane and a second conductor plane is a power plane.

4. The circuit board as claimed in claim 1, wherein the first and second conductor planes and the conductive material in build-up vias are formed of the same metal.

5. The circuit board as claimed in claim 4, wherein the metal is copper.

6. A circuit board, comprising:
a first conductor plane with a first fixed potential;
a dielectric layer formed on the first conductor plane;
at least a via formed in the dielectric layer and filled with a conductive material; and
a second conductor plane with a second fixed potential, in contact with the conductive material in the via;
wherein distances of the via substantially equal one fourth of a signal wavelength.

7. The circuit board as claimed in claim 6, wherein the first conductor plane is a power plane and a second conductor plane is a ground plane.

8. The circuit board as claimed in claim 6, wherein the first conductor plane is a ground plane and a second conductor plane is a power plane.

9. The circuit board as claimed in claim 6, wherein the first and second conductor planes and the conductive material in build-up vias are formed of the same metal.

10. The circuit board as claimed in claim 9, wherein the metal is copper.
